(19) United States
(12) Patent Application Publication
(10) Pub. No.: US 2002/0064004 A1
(43) Pub. Date: May 30, 2002

(54) Magnetoresistive double spin filter tunnel junction

(76) Inventor: Daniel C. Worledge, Poughquag, NY (US)

Correspondence Address: MAREK ALBOSZTA, LUMEN INTELLECTUAL PROPERTY SERVICES, SUITE 110, 45 CABOT AVENUE, SANTA CLARA, CA, 95051, US

(21) Appl. No.: 09/924,409

(22) Filed: Aug. 7, 2001

Related U.S. Application Data
(60) Provisional application No. 60/224,175, filed on Aug. 9, 2000.

(51) Int. Cl. G11B 5/39; G11C 11/15

(52) U.S. Cl. 360/324.2; 365/158

(57) ABSTRACT

A dual spin filter tunnel junction and a method of operating the junction to control the tunneling of charge carriers. The tunnel junction has a polarization-selective barrier profile for charge carriers and is made of a first spin filter and a second spin filter adjacent the first spin filter. The first spin filter has a first magnetization M₁ and the second spin filter has a second magnetization M₂ and the relation between magnetizations M₁, M₂ such as their relative alignment is alterable, e.g., by applying an external magnetic field to change the orientation of either M₁ or M₂ or both, thereby changing the polarization-selective barrier profile to control the tunneling of the charge carriers. The dual spin filter tunnel junction has an excellent ratio of high to low resistance Rₕᵢ/R_{low} and can be used in sensors, nonvolatile memories and other devices relying on magnetically induced resistance changes.

### RELATED APPLICATIONS

This application claims priority from provisional application 60/224,175 filed on Aug. 9, 2000, which is herein incorporated by reference.

### FIELD OF INVENTION

The present invention relates generally to magnetoresistive tunnel junctions utilizing double spin filters for polarization-selective tunneling of polarized charge carriers.

### BACKGROUND OF THE INVENTION

The fundamental principles of magnetoresistance (MR) including anisotropic magnetoresistance (AMR), giant magnetoresistance (GMR) and spin tunneling have been well-known in the art for some time. For example, in the field of magnetic recording three general types of magnetoresistive devices are used as magnetic readback sensors: the anisotropic magnetoresistive (AMR) sensor, the giant magnetoresistive (GMR) sensor or GMR spin valve and tunnel valve sensor. The construction of these sensors is discussed in the literature, e.g., in U.S. Pat. No. 5,159,513 or U.S. Pat. No. 5,206,590. Furthermore, the now standard magnetoresistive tunnel junction is described in U.S. Pat. No. 5,629,922.

Magnetoresistive sensors rely on a ferromagnetic free layer to detect an external magnetic field. The free layer typically has a low coercivity H_{c} and low anisotropy and thus an easily movable or rotatable magnetic moment M which responds to the external field. The rotation of the free layer's magnetic moment M causes a change in the resistance of the device by a certain value ΔR as measured between two electrical contacts or electrodes. In general, the larger the value of ΔR in relationship to the total resistance R, i.e., the larger ΔR/R the better the sensor. This change in resistance due to rotation of the magnetization M of the free layer can be sensed and used in practical applications including sensors and nonvolatile memory.

Since the demonstration of large room temperature magnetoresistance (MR) in magnetic tunnel junctions, interest has developed in ferromagnet/insulator/ferromagnet (F/I/F) tunneling due to possible applications in sensors and nonvolatile memory. Unfortunately, the MR effect in such F/I/F tunnel junctions is limited by the spin-polarizations of the ferromagnetic electrodes. Even for 100% spin-polarized electrodes the MR effect is limited by the fact that the electrodes are only 100% spin-polarized at 0° K., but not at room temperature. In fact, the polarization of known F/I/F tunnel junctions would be reduced to about 70% at room temperature and even more above room temperature, i.e., at the operating temperature of a device employing an F/I/F tunnel junction. Hence the ratio of Rₕᵢ/R_{low} (where Rₕᵢ is the highest resistance state and R_{low}, is the lowest resistance state) for such devices would be low and even under ideal conditions would not be expected to exceed 4 at room temperature.

It is known in the art that electrons of different polarizations or spin states, e.g., spin-up and spin-down, have different tunneling probabilities through a magnetic insulating layer. This effect is due to different potential barrier heights seen by the spin-up and spin-down electrons due to Zeeman splitting caused by the magnetization of the magnetic insulating layer. The effect can be used to select or filter electrons based on their polarization. The idea of a magnetic insulating layer acting as a spin filter is described by X. Hao et al. in “Spin-Filter Effect of Ferromagnetic Europium Sulfide Tunnel Barriers”, Physical Review B, Vol. 42, No. 13, Nov. 1, 1990, pp. 8235 and by J. S. Moodera, et al. in “Electron-Spin Polarization in Tunnel Junctions in Zero Applied Field with Ferromagnetic EuS Barriers”, Physical Review Letters, Vol. 61, No. 5, Aug. 1, 1988, pp. 637.

Further improvements in an EuSe spin filter introduced by increased Zeeman splitting, i.e., increased difference in potential barrier as seen by spin-up and spin-down electrons in the presence of an external magnetic field are described by J. S. Moodera et al. in “Variation of the Electron-Spin Polarization in EuSe Tunnel Junctions from Zero to Near 100% in a Magnetic Field”, Physical Review Letters, Vol. 70, No. 6, Feb. 8, 1993, pp. 853.

More recently, the use of a single spin filter layer sandwiched between ferromagnetic layers has been proposed for producing a modest increase in the performance of F/I/F tunnel junctions. Further information on this subject is provided by P. LeClair et al. in “Ferromagnetic-Ferromagnetic Tunneling and the Spin Filter Effect”, Journal of Applied Physics, Vol. 76, No. 10, Nov. 15, 1994, pp. 6546. Additional applications of single spin filters for injecting electrons of a certain spin into semiconductors and measuring certain spins for quantum computing are discussed by J. C. Egues in “Spin-Dependent Perpendicular Magnetotransport through a Tunable ZnSe/Zn₁₋ₓMnₓSe Heterostructure: A Possible Spin Filter?”, Physical Review Letters, Vol. 80, 1998, pp. 4578; and by David P. DiVincenzo in “Quantum Computing and Single-Qubit Measurements Using the Spin-Filter Effect”, Journal of Applied Physics, Vol. 85, 1999, pp. 4785 respectively.

Still more recent studies of polarized electrons tunneling through single ferromagnetic barriers in modified tunnel junctions are discussed by Ching-Ray Chang, et al. in “Spin Polarized Tunneling through a Ferromagnetic Barrier”, Chinese Journal of Physics, Vol. 36, No. 2-I, April 1998, pp. 85. In this case a single magnetic insulator is used as the tunneling barrier layer sandwiched in between a ferromagnetic metal electrode and a normal metal electrode.

Unfortunately, the prior art spin filters do not exhibit a high enough spin selectivity to electrons, or charge carriers in general, at room temperature. Furthermore, they are not well-suited for use in sensors, nonvolatile memories and a host of other applications which would greatly benefit from devices built around a spin filter. Specifically, tunnel junctions using a single spin filter in accordance with the prior art have poor ΔR/R ratios and do not operate well in weak external magnetic fields.

### OBJECTS AND ADVANTAGES

Accordingly, it is a primary object of the present invention to provide a tunnel junction taking advantage of spin filters for improved polarization selectivity to charge carriers. Furthermore, tunnel junctions of the invention should exhibit improved performance in a wide range of temperatures including room temperature and above.

It is a further object of the invention to improve the Rₕᵢ/R_{low} ratio in tunnel junctions employing spin filters and to render them efficient in weak external magnetic fields.

Yet another object of the invention is to provide devices employing spin filters.

Still another object of the invention is to offer a method for controlling the tunneling of charge carriers through dual spin filter tunnel junctions by controlling the profile of the tunnel junction's barrier.

### SUMMARY OF THE INVENTION

The objects and advantages set forth are achieved by a dual spin filter tunnel junction having a polarization-selective barrier profile for charge carriers, a first spin filter and a second spin filter adjacent the first spin filter. The first spin filter has a first magnetization M₁ and the second spin filter has a second magnetization M₂. A relation exists between the first and second magnetizations M₁, M₂ and this relation is alterable, e.g., by applying an external magnetic field. In particular, the relation between magnetizations M₁, M₂ can be altered by changing the orientation of one or both magnetizations M₁, M₂ and/or changing one or both of their magnitudes.

In one embodiment, the first spin filter has a first magnetic coercivity H_{c1} and the second spin filter has a second magnetic coercivity H_{c2} such that H_{c2}<H_{c1}. For example, second spin filter is a free layer and its second magnetization M₂ is responsive to or alterable by an external magnetic field. In another or in the same embodiment the first spin filter can be a pinning layer for controlling the relation between magnetizations M₁, M₂, e.g., for aiding in altering the orientation of second magnetization M₂ of the free layer. More precisely, the pinning layer can be employed to ensure stability of parallel and anti-parallel alignment between first and second magnetizations M₁, M₂.

An interface exists between the first and second spin filters. In one embodiment the interface consists of an insulator layer. In another embodiment the interface has a structure for breaking exchange coupling between the first and second spin filter layers. In yet another embodiment the interface is a lattice mis-matched interface. This can be accomplished, for example, when the two spin filters have different crystal structures. For example, ferro spinels and garnets can be used as materials for first and second spin filter layers. Selecting the first spin filter layer to be made of one type of material and the second spin filter layer to be made of another is one exemplary way of ensuring such lattice mis-matched interface. In any event, it is important that the interface be devoid of intermediate energy states.

In yet another embodiment an antiferromagnetic layer can be provided adjacent the tunnel junction. Such antiferromagnetic layer can be used to pin the pinning layer which can deteriorate over time.

The dual spin filter tunnel junction of the invention can be used in many devices such as sensors and nonvolatile memories. In fact, any device using resistance change in response to an external magnetic field for performing its function can benefit from the dual spin filter tunnel junction distinguishing between polarizations of charge carriers, e.g., spin-up and spin-down polarizations of electrons. Devices employing the tunnel junction of the invention can have a source for providing an external magnetic field for rotating the second magnetization M₂ of the second spin filter layer, especially when this second spin filter layer is used as a free layer.

A device employing the tunnel junction of the invention can further include an electrode for supplying the charge carriers. Typically, two electrodes on opposite sides of the tunnel junction are used. The charge carriers tunnel from one electrode to the other through the tunnel junction. Preferably, the electrode or electrodes are metal-oxide electrodes.

The invention includes a method for controlling the tunneling of charge carriers, e.g., electrons, through a polarization-selective barrier profile of a dual spin filter tunnel junction. An applied electric field is applied across the tunnel junction to promote the tunneling of the charge carriers. Control of the tunneling is obtained by altering the relation between first and second magnetizations M₁, M₂ of the spin filter layers and thereby changing the polarization-selective barrier profile of the tunnel junction. Conveniently, the relation can vary between two states such as parallel and anti-parallel alignment of magnetizations M₁, M₂. An external magnetic field can be applied to reverse the second magnetization M₂. Reversing the external magnetic field can then switch the magnetizations from being aligned parallel to anti-parallel and vice versa.

The tunnel junction of the invention can be operated in various temperature ranges. For example, the tunnel junction can operate at in the cryogenic temperature regime, room temperature regime and any higher device operating temperature regime while remaining below a critical temperature T_{c} at which the spin layers lose their magnetic properties.

The specific embodiments of the invention are described in the detailed description with reference to the attached drawing figures.

### BRIEF DESCRIPTION OF THE FIGURES

FIG. 1 is a schematic diagram illustrating a dual spin filter tunnel junction according to the invention.

FIG. 2 is an energy level diagram showing the energy levels in the layers of a device employing a tunnel junction of the invention.

FIG. 3A illustrates a barrier profile for parallel alignment of magnetizations in the spin filter layers a tunnel junction of the invention.

FIG. 3B illustrates a barrier profile for anti-parallel alignment of magnetizations in the spin filter layers of a tunnel junction of the invention.

FIG. 4 is schematic diagram of a tunnel junction with an insulating layer between the two spin filter layers.

FIG. 5 is a schematic diagram of a tunnel junction with an adjacent antiferromagnetic layer.

### DETAILED DESCRIPTION

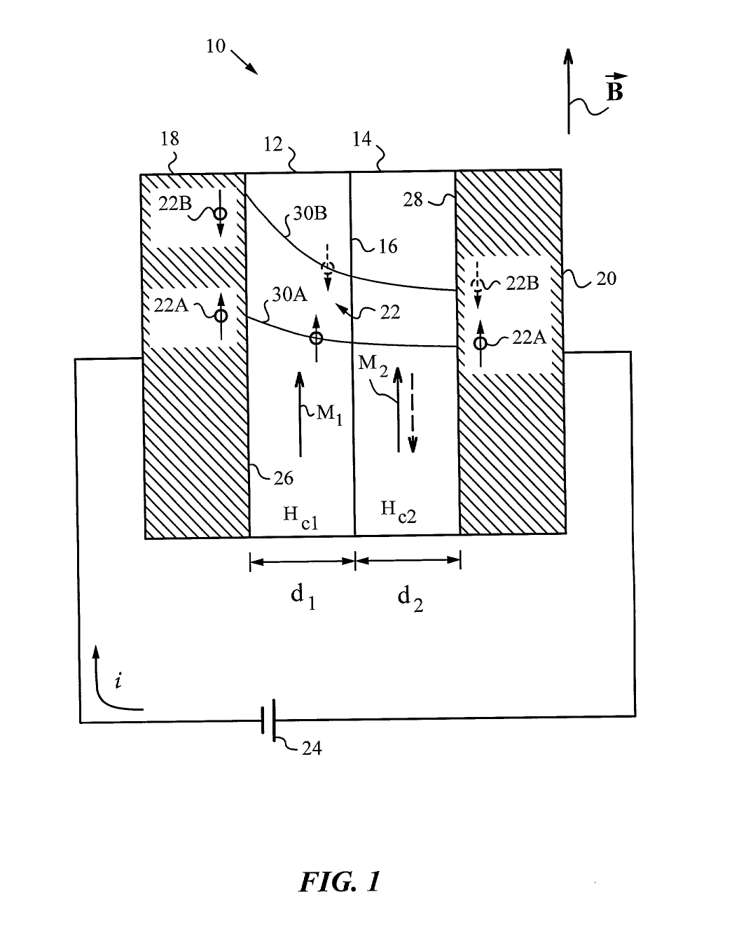

FIG. 1 illustrates a tunnel junction 10 built up of a first spin filter 12 and a second spin filter 14 in accordance with the invention. Spin filters 12, 14 are both in the form of magnetic and insulating layers and have thicknesses d₁ and d₂, respectively. These two layers 12, 14 form the tunnel barrier of tunnel junction 10. It is important that each of layers 12, 14 be uniform and free of pin-holes. Also, an interface 16 between adjacent spin filter layers 12, 14 has to be free of intermediate energy states.

First spin filter layer 12 has a first magnetic coercivity H_{c1} and a first magnetization M₁. Second spin filter layer 14 has a second magnetic coercivity H_{c2} and a second magnetization M₂. The magnetizations are indicated by arrows. The magnetic coercivities H_{c1} and H_{c2} of first and second spin filter layers 12, 14 are chosen such that H_{c2}<H_{c1}. In fact, H_{c1} can be much larger than H_{c2} such that first magnetization M₁ does not change under the influence of an external magnetic field B, indicated by an arrow in FIG. 1, while second magnetization M₂ is easily altered, in this case reversed by external magnetic field B. It should be noted, however, that in general the relation between the first and second magnetizations M₁, M₂ can be altered by changing the orientation and/or magnitude of either or both magnetizations. Such change in orientation and/or magnitude of magnetization can involve any mechanism by which external field B interacts with the spin filter layers such as partial domain re-orientation or coherent rotation of domains.

Conveniently, the present embodiment utilizes external field B to alter the relation between the magnetizations by reversing second magnetization M₂. In particular, a reversal in direction of magnetic field B from that shown in FIG. 1 will change the alignment between M₁ and M₂ from parallel to anti-parallel by flipping the direction of M₂ by 180°. Thus, second spin filter layer 14 acts as a free layer, rotating freely in response to external magnetic field B. Meanwhile, first spin filter layer 12 acts as a pinned layer. A person skilled in the art will be able to select the appropriate difference between H_{c1} and H_{c2} of the pinned and free layers 12, 14 depending on the application of tunnel junction 10 and the strength of external magnetic field B.

A first electrode 18, e.g., in the form of an electrode layer is positioned next to first spin filter layer 12. A second electrode 20, e.g., also in the form of a layer is positioned next to second spin filter layer 14. A first interface 26 exists between first electrode 18 and first spin filter layer 12. Similarly, a second interface 28 exists between second electrode 20 and second spin filter layer 14.

Charge carriers 22 of a first polarization 22A and second polarization 22B, as indicated by arrows, are supplied for tunneling from first electrode 18 to second electrode 20 through tunnel junction 10. Preferably, electrodes 18, 20 are connected to a source 24 for supplying charge carriers 22 in the form of a current i. Source 24 also applies an electric field across tunnel junction 10 to promote tunneling of charge carriers 22.

Charge carriers 22 can be positive or negative charge carriers. If charge carriers 22 are electrons then first polarization 22A is a spin-up polarization while second polarization 22B is a spin-down polarization.

The resistance of tunnel junction 10 is different when magnetizations M₁, M₂ are aligned parallel and anti-parallel. When magnetizations M₁, M₂ are parallel aligned electrons 22A have a large tunneling probability and electrons 22B have a low tunneling probability. The tunneling probabilities for electrons 22A, 22B are generally exponential in both the thickness and square root of the barrier height and are related to the wavefunction of spin-up and spin-down electrons. For better visualization, graphs 30A, 30B indicate the wavefunctions for spin-up and spin-down electrons tunneling from left to right.

When magnetizations M₁, M₂ are parallel aligned a large number of spin-up electrons 22A will tunnel while only a few spin-down electrons 22B will do the same. This difference in tunneling probability is indicated by using a dashed line to draw spin-down electrons 22B which tunnel. When magnetizations M₁, M₂ are anti-parallel, both spin-up and spin-down electrons 22A, 22B will have a low tunneling probability and only a few of each will tunnel. Hence the resistance of tunnel junction 10 is low when magnetizations M₁, M₂ are parallel and high when anti-parallel.

FIGS. 3A and 3B illustrate a polarization-selective barrier profile of tunnel junction 10 for spin-up and spin-down electrons 22A and 22B with parallel and anti-parallel alignment of magnetizations M₁, M₂. In particular, FIG. 3A shows a barrier profile 32 in dashed line encountered by spin-up electrons 22A and a barrier profile 34 encountered by spin-down electrons 22B for parallel alignment of magnetizations M₁, M₂.

Spin-up electrons 22A encounter lower barrier 32, of the same effective height in both first and second spin filter layers 12, 14. Spin-down electrons 22B encounter a higher barrier 34 also of the same effective height in first and second spin filter layers 12, 14. It should be noted that it is not necessary that lower barrier 32 have the same effective height in both first and second spin filter layers 12, 14. However, it is important that the difference in the effective height of barriers 32 and 34 defining an exchange splitting J between the up- and down-energy bands in spin filters 12, 14 be maximized.

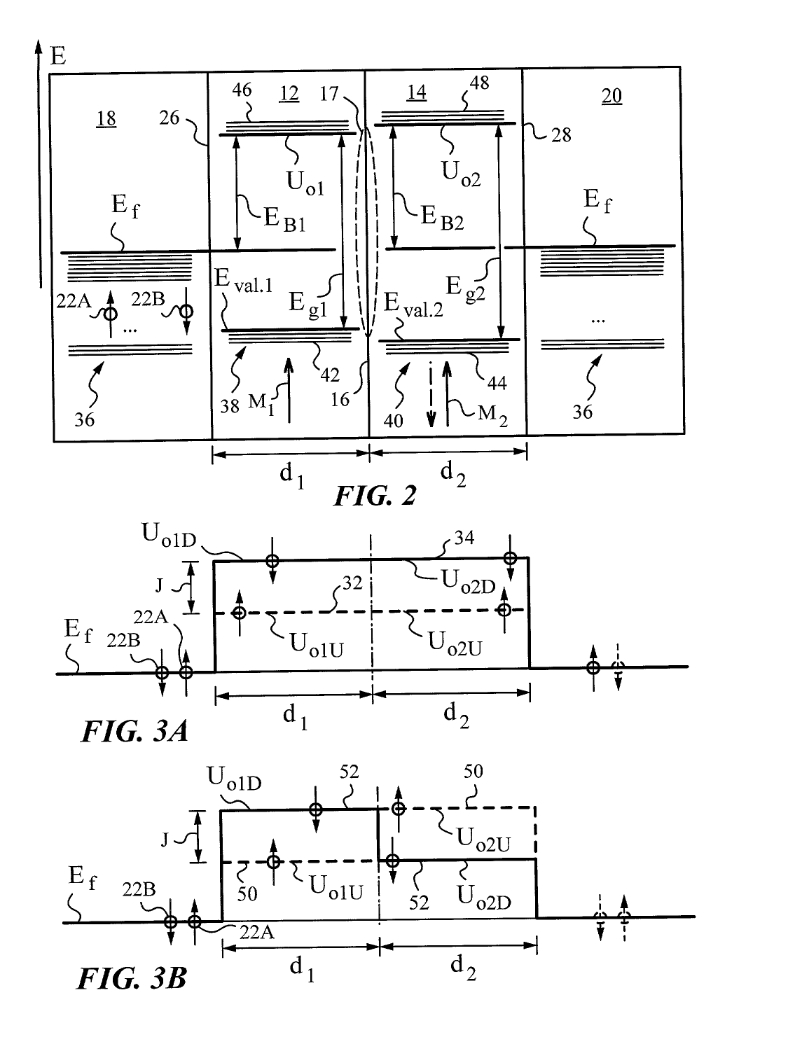

The energy level diagram of FIG. 2, where the axis labeled E indicates increasing energy, visualizes in more detail the energy levels seen by spin-up and spin-down electrons 22A, 22B in tunnel junction 10. In electrode 18 both spin-up and spin-down electrons 22A, 22B are in a number of essentially continuous or gapless energy states 36 below and up to a Fermi Energy E_{f}. Likewise, in electrode 20 electrons 22A, 22B are in energy states 36 limited by Fermi Energy E_{f}. A person skilled in the art will recognize that this energy level structure is typical for conductive materials of which electrodes 18, 20 are made.

Spin filter layers 12, 14 are made of insulators and hence exhibit a different energy level structure. Both layers 12, 14 have energy level structures 38, 40 separated into valence bands 42, 44 and conduction bands 46, 48 respectively. Valence bands 42, 44 are limited by upper valence band energies Eᵥₐₗ₁ and Eᵥₐₗ₂ respectively. Conduction bands 46, 48 start at lowest conduction band energies Uₒ₁ and Uₒ₂ respectively. The energy differences between upper valence band energies Eᵥₐₗ₁ and Eᵥₐₗ₂ and lowest conduction band energies Uₒ₁ and Uₒ₂ are called bandgaps E_{g1} and E_{g2} respectively and their typical values are about 0.5 eV.

In agreement with well-known principles of physics, since electrodes 18, 20 are in contact with layers 12, 14 the Fermi Energy E_{f} for all four layers is lined up, as shown. From the Fermi Energy E_{f} level electrons 22A, 22B initially see a barrier height E_{B1} in spin filter layer 12 and a barrier height E_{B2} in spin filter layer 14.

Magnetizations M₁, M₂ affect energy level structures 38, 40 by adjusting barrier heights E_{B1} and E_{B2} of upper energy levels 46, 48 depending on the polarizations, i.e., spin states of electrons 22A, 22B. In particular, in spin filter layer 12 magnetization M₁ points up and introduces exchange splitting J of lowest conduction band energy Uₒ₁ into two levels U_{o1U} and U_{o1D} as indicated in FIG. 3A. As a result, spin-up electrons 22A see a lower lowest conduction band energy U_{o1U} in spin filter layer 12 than do spin-down electrons 22B. The latter see a higher lowest conduction band energy U_{o1D}. The same splitting occurs in spin filter layer 14 when magnetization M₂ points up, i.e., when it is aligned parallel with magnetization M₁. Specifically, spin-up electrons 24 see a lower lowest conduction band energy U_{o2U} in spin filter layer 14 and spin-down electrons see a higher lowest conduction band energy U_{o2D}. In this case tunneling of spin-up electrons 22A through tunnel junction 10 is more probable than tunneling of spin-down electrons 22B. Again, this is apparent in FIG. 3A, where barrier profile 32 is low in both layers 12, 14 for spin-up electrons due to lower heights E_{B1}=U_{o1U}−E_{f} and E_{B2}=U_{o2D}−E_{f}. Meanwhile, barrier profile 34 is higher for spin-down electrons 22B in both layers 12, 14 due to larger barrier heights E_{B1}=U_{o1D}−E_{f} and E_{B2}=U_{o2D}−E_{f}. The difference between the heights of barrier profiles 32 and 34 is equal to exchange splitting J.

It should be noted, that in a practical situation spin filter layers 12, 14 will each exhibit a different exchange splitting J. For example, layer 12 will show a first exchange splitting J₁ and layer 14 will show a second exchange splitting J₂. In this case it is also important for efficient operation of tunnel junction 10 that the exchange splittings J₁, J₂ be maximized.

When magnetization M₂ is anti-parallel aligned with respect to magnetization M₁, the exchange splitting J reverses the heights of lowest conduction band energies U_{o2U} and U_{o2D} for spin-up and spin-down electrons 22A, 22B in spin filter layer 14. Thus, spin-up electrons 22A encounter a barrier profile 50 indicated in dashed line and spin-down electrons 22B encounter a barrier profile 52, as shown in FIG. 3B. Barrier profile 50 has a higher barrier height E_{B1}=U_{o1D}−E_{f} for spin-down electrons 22B in layer 12 and a lower barrier height E_{B2}=U_{o2D}−E_{f} for spin-down electrons 22B in layer 14. Barrier profile 52 has a lower barrier height E_{B1}=U_{o1U}−E_{f} for spin-up electrons 22A in layer 12 and a higher barrier height E_{B2}=U_{o2U}−E_{f} for spin-up electrons 22A in layer 14. Thus, both spin-up and spin-down electrons 22A, 22B encounter a combination of lower and higher barrier heights in tunnel junction 10. Consequently, the tunneling probability of both spin-up and spin-down electrons 22A, 22B is reduced.

In designing dual spin filter junction 10 a person skilled in the art will have to make adaptations to particular operating conditions and requirements by selecting appropriate design parameters and materials. The below example is provided to merely illustrate these conditions and requirements in a few particular cases.

Conveniently, the relation between magnetizations M₁, M₂ is designed to be altered substantially by an external magnetic field B, e.g., between parallel and anti-parallel alignment. In this case the choice of design parameters is related to basic principles of magnetoresistance in adjacent spin filter layers 12, 14 for parallel and anti-parallel alignment of magnetizations M₁, M₂. The electrical conductances G of layers 12, 14 for parallel and anti-parallel alignments of magnetizations M₁, M₂ are given by:

$$\begin{matrix}{G}_{↑ ↑} = {G}_{o} [ {T}_{P}^{1} {T}_{P}^{2} + {T}_{AP}^{1} {T}_{AP}^{2} ] & ( 1 A ) \\ {G}_{↑ ↓} = {G}_{o} [ {T}_{P}^{1} {T}_{AP}^{2} + {T}_{AP}^{1} {T}_{P}^{2} ] , & ( 1 B )\end{matrix}$$

where the subscripted arrows on G indicate the relation between magnetizations M₁, M₂, i.e., ↑↑ stand for parallel alignment and ↑↓ stand for anti-parallel alignment.

$${T}_{P ( AP )}^{1 ( 2 )}$$

is the transmission coefficient, superscripts 1, 2 denote spin filter layers 12, 14 respectively and subscripts P, AP denote parallel and anti-parallel alignment between electron spin and layer magnetization. Gₒ is a constant.

In a particular case when thicknesses d₁l, d₂ are chosen equal and transmission coefficients for layers 12, 14 are equal or nearly equal the ratio of electrical conductances for parallel and anti-parallel alignments becomes:

$$\frac{{G}_{↑ ↑}}{{G}_{↑ ↓}} = \frac{{( {T}_{P} )}^{2} + {( {T}_{AP} )}^{2}}{2 {T}_{P} {T}_{AP}} . \qquad ( 2 )$$

For high performance of junction 10 the values of transmission coefficients T_{P} and T_{AP} for parallel and anti-parallel alignments between spins of electrons 24 and magnetizations M₁, M₂ should be very different. In fact, high spin selectivity to electrons 24 rendering junction 10 highly sensitive is achieved when (T_{AP})²<<(T_{P})². Using this last inequality equation (2) can be simplified as follows:

$$\frac{{G}_{↑ ↑}}{{G}_{↑ ↓}} \approx \frac{{( {T}_{P} )}^{2}}{2 {T}_{P} {T}_{AP}} = \frac{{T}_{P}}{2 {T}_{AP}} . \qquad ( 3 )$$

In the free electron approximation the transmission coefficients T_{P}, T_{AP} are given by:

T_{P}=Tₒexp[−2K_{P}d] (4a)

T_{AP}=Tₒexp[−2K_{APd}], (4b)

where d is the thickness of the spin filter layer and K_{A}, K_{AP} are the wavevectors for electrons whose spins are parallel and anti-parallel to the magnetization of that layer. In particular:

$$\begin{matrix}{κ}_{P} = \sqrt{\frac{2 m ( {U}_{oU} - {E}_{f} )}{{ℏ}^{2}}} & ( 5 a ) \\ {κ}_{AP} = \sqrt{\frac{2 m ( {U}_{oD} - {E}_{f} )}{{ℏ}^{2}}} , & ( 5 b )\end{matrix}$$

where m is the electron mass. As defined above, U_{oU} is the lower lowest conduction band energy, U_{oD} is the higher lowest conduction band energy, U_{oU}−E_{f} is the barrier height for electrons with spin parallel to the magnetization of that layer, and U_{oD}−E_{f} is the barrier height for electrons with spin anti-parallel to the magnetization of that layer (see FIG. 2).

Using equations (4) and (5) the ratio of conductances for parallel and anti-parallel alignment of the magnetic layers becomes:

$$\frac{{G}_{↑ ↑}}{{G}_{↑ ↓}} = \frac{1}{2} exp [ 2 d Δ κ ] , \qquad ( 6 )$$

where ΔK=K_{AP}−K_{P}. Thus, the magnetoresistance of spin filter layers 12, 14 exhibits an exponential dependence on the relative alignment of magnetizations M₁, M₂. Clearly, the larger this ratio, the higher the performance of junction 10. Specifically, when magnetizations M₁, M₂ are parallel junction 10 offers a low resistance R₁ which is equal to 1/G_{↑↑}. When magnetizations M₁, M₂ are anti-parallel junction 10 offers a high resistance R₂ which is equal to 1/G_{↑↓}. The performance of junction 10 can thus be characterized by the ratio:

$$\frac{{R}_{↑ ↑}}{{R}_{↑ ↓}} = \frac{{G}_{↑ ↓}}{{G}_{↑ ↑}} , \qquad ( 7 )$$

where R is the nominal resistance of tunnel junction 10 inclusive electrodes 18, 20. For tunnel junction 10 the difference between low and high resistance states as expressed by R_{↑↓}/R_{↑↑=R}_{low}/Rₕᵢ can be on the order of 10⁵ or even higher.

The ratio R_{↑↑}/R_{↑↓} increases as the ratio of conductances increases. From equation 6 it is apparent that the ratio of conductances can be increased by increasing the thickness d of layers 12, 14. Excessive increase in thickness d, however, will increase the overall resistance R of tunnel junction 10 and produce a higher RC time constant. Hence, the reaction time of junction 10 will be longer. A person skilled in the art will strike the appropriate compromise between the desired R_{↑↓}/R_{↑↑} ratio for high sensitivity and minimum required reaction time of tunnel junction 10.

A large value of ΔK also increases the R_{↑↓}/R_{↑↑} ratio and can be achieved by making layers 12, 14 of materials exhibiting a large exchange splitting J. In other words U_{oU}−E_{f} should be much larger than U_{oD}−E_{f} as clarified by equations 5a&b.

For example, when layers 12, 14 are made of materials with small bandgaps E_{g1}, E_{g2}, e.g., on the order of 1.4 eV, and large exchange splittings J₁, J₂, the value of ΔK can be about 0.1/Å producing a large magnetoresistance. For barrier heights E_{B1}, E_{B2} of 0.7 eV (assuming that the Fermi energy E_{f} lies at or near the center of bandgaps E_{g1}, E_{g2}) J₁/2 for layer 12 and J₂/2 for layer 14 are about 0.46 eV and one obtains ΔK=1/(3.15 Å). When the thickness of each layer d₁=d₂=20 Å of layers 12, 14 this yields, by substituting into equation 6, a conductance ratio of about 10⁵.

In addition to the above design parameters, the materials of layers 12, 14 are selected from among insulating materials with no states in bandgaps E_{g1}, E_{g2} and with magnetic properties, i.e., with suitably large exchange splittings J₁, J₂. Insulating ferromagnets can be used when tunnel junction 10 is operated in a low temperature range, particularly in the cryogenic temperature range. These insulating ferromagnets are materials such as (La₁₋ₓSrₓ)MnO₃ and related materials in which La is replaced with other rare earth metals and Sr is replaced by Pb, Ca and Ba. A person of average skill in the art will know how to adjust the value of x to obtain the desired properties. In particular, (La_{0.9}Sr_{0.1})MnO₃ or (La_{0.9}Ca_{0.1})MnO₃ can be used, where x=0.1for both Sr and Ca.

At higher temperatures, specifically at room temperature and higher operating temperatures insulating ferromagnets lose their insulating properties. Hence, layers 12, 14 are preferably made of insulating ferrimagnets when tunnel junction 10 is to operate above cryogenic temperatures. Insulating ferrimagnets can be selected from materials having the crystal structure of spinels or garnets. Suitable spinels include materials such as CoFe₂O₄, Li_{0.5}Fe_{2.5}O₄, Mn_{0.5}Zn_{0.5}Fe₂O₄. Suitable garnets include materials such as Y₃Fe₅O₁₂, Y₃Fe₍₅₋₂ₓ₎CoₓGeₓO₁₂.

Of course, above a certain critical temperature T_{c} the insulating and magnetic materials of layers 12, 14 lose their magnetic properties. Thus, tunnel junction 10 has to be operated below this critical temperature T_{c}.

In addition, materials of layers 12, 14 are grown or deposited such that interface 16 is devoid of intermediate energy states, i.e., energy states falling within either bandgap E_{g1} or bandgap E_{g2}. This is achieved when layers 12, 14 and interface 16 present no anomalies in an interface region 17 around actual interface 16. This, in turn, is ensured by maintaining good epitaxy and sharp interface 16 during manufacture.

Furthermore, the energy difference between upper valence band energies Eᵥₐₗ₁ and Eᵥₐₗ₂ and between lowest conduction band energies Uₒ₁ and Uₒ₂ are preferably within a few tenths of eV of each other. This condition ensures that barrier profiles are uniform and it minimizes reflections of charge carriers.

It is also important that any exchange coupling existing between layers 12, 14 be broken. Proper choice of materials of layers 12 and 14 can produce interface region 17 to accomplish this goal. For example, exchange coupling is broken when one of layers 12, 14 is made of a garnet and the other of a spinel, which have different crystal structures. In fact, exchange coupling is broken when interface 16 is a lattice mismatched interface. Alternatively, interface region 17 can have a crystalline structure different from either layer 12, 14 to thus break the exchange coupling.

The materials of electrodes 18, 20 are made of a conductor and selected to match with layers 12, 14 such that interfaces 26, 28 and do not interfere with operation of layers 12, 14. The materials of electrodes 18, 20 can be oxide metals such as SrRuO₃, RuO₂, In₂O₃, Sn₂O₃. It is particularly advantageous to use these materials in electrodes 18, 20 when layers 12, 14 are made of oxides.

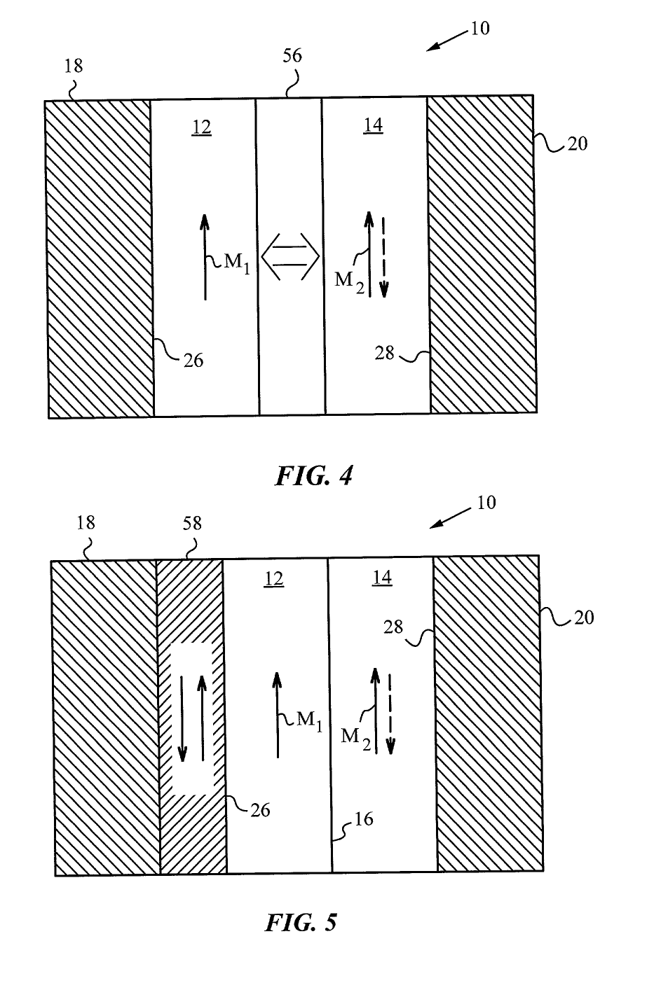

FIG. 4 illustrates an alternative embodiment of tunnel junction 10 having an additional insulator layer 56 interposed between pinned layer 12 and free layer 14. Insulator layer 56 has no magnetic properties and can be selected from materials such as Al₂O₃. The purpose of insulator layer 56 is to break the exchange coupling. At the same time, insulator layer 56 has to be selected such that electrons 24 tunnel through it and overall resistance R of tunnel junction 10 remains low.

FIG. 5 shows yet another embodiment of tunnel junction 10 in which an antiferromagnetic (AF) layer 58 is inserted between electrode 18 and pinned layer 12. The purpose of AF layer 58 is to stabilize the rotation of magnetization M₂ of free layer 14 by pinning pinned layer 12. Since pinned layer 12 has a tendency to deteriorate with time, such arrangement ensures long term stability of tunnel junction 10. The specifics of using AF layers for this purpose are known in the art. Alternatively, antiferromagnetic layer 58 can be a part of electrode 18.

Any device using resistance change in response to external magnetic field B for performing its function can benefit from the dual spin filter tunnel junction 10 distinguishing between polarizations of charge carriers, e.g., spin-up and spin-down polarizations of electrons 24. For example, when free layer 14 has a square hysteresis loop tunnel junction 10 can be used in a memory device as a nonvolatile memory element. When free layer 14 has a tilted hysteresis loop tunnel junction 10 can be used in a sensing device as the sensing element. Devices employing tunnel junction 10 can have an additional source for providing a controlled external magnetic field B for rotating magnetization M₂ of the layer 14. This would be especially useful in a memory device.

Although the present invention and its advantages have been described in detail, it should be understood that various changes, substitutions, and alternations can be made herein without departing from the principle and the scope of the invention. Accordingly, the scope of the present invention should be determined by the following claims and their legal equivalents.

What is claimed is:

1. A tunnel junction having a polarization-selective barrier profile for charge carriers, said tunnel junction comprising:
a) a first spin filter; and
b) a second spin filter adjacent said first spin filter.

2. The tunnel junction of claim 1, wherein a relation between a first magnetization M₁ of said first spin filter and a second magnetization M₂ of said second spin filter is alterable.

3. The tunnel junction of claim 2, wherein said first spin filter has a first magnetic coercivity H_{c1} and said second spin filter has a second magnetic coercivity H_{c2} such that H_{c2}<H_{c1}.

4. The tunnel junction of claim 2, wherein said second spin filter is a free layer.

5. The tunnel junction of claim 2, wherein said first spin filter is a pinning layer for altering said relation.

6. The tunnel junction of claim 1, further comprising an interface between said first spin filter and said second spin filter.

7. The tunnel junction of claim 6, wherein said interface comprises an insulator layer.

8. The tunnel junction of claim 6, wherein said interface comprises an interface region for breaking exchange coupling between said first spin filter and said second spin filter.

9. The tunnel junction of claim 6, wherein said interface comprises a lattice mis-matched interface.

10. The tunnel junction of claim 6, wherein said interface is devoid of intermediate energy states.

11. The tunnel junction of claim 1, wherein at least one of said first spin filter and said second spin filter is made of a material selected from the group consisting of ferro spinels and garnets.

12. The tunnel junction device of claim 1, further comprising an antiferromagnetic layer adjacent said tunnel junction.

13. An apparatus for controlling charge carrier transmission having a tunnel junction having a polarization-selective barrier profile distinguishing a first polarization and a second polarization of said charge carriers, said tunnel junction comprising:
a) a first spin filter; and
b) a second spin filter adjacent said first spin filter.

14. The apparatus of claim 13, wherein a relation between a first magnetization M₁ of said first spin filter and a second magnetization M₂ of said second spin filter is alterable.

15. The tunnel junction of claim 14, wherein said first spin filter layer has a first magnetic coercivity H_{c1} and said second spin filter layer has a second magnetic coercivity H_{c2} such that H_{c2}<H_{c1}.

16. The tunnel junction of claim 14, wherein said second spin filter is a free layer.

17. The tunnel junction of claim 14, wherein said first spin filter is a pinning layer for altering said relation.

18. The apparatus of claim 14, further comprising a source for providing an external magnetic field for altering said second magnetization M₂.

19. The apparatus of claim 13, further comprising an interface between said first spin filter and said second spin filter.

20. The apparatus of claim 19, wherein said interface comprises an insulator layer.

21. The apparatus of claim 19, wherein said interface comprises an interface region for breaking exchange coupling between said first spin filter and said second spin filter.

22. The apparatus of claim 19, wherein said interface comprises a lattice mis-matched interface.

23. The apparatus of claim 19, wherein said interface is devoid of intermediate energy states.

24. The apparatus of claim 13, wherein at least one of said first spin filter and said second spin filter layer is made of a material selected from the group consisting of ferro spinels and garnets.

25. The apparatus of claim 13, further comprising an antiferromagnetic layer positioned next to said tunnel junction.

26. The apparatus of claim 13, further comprising an electrode for supplying said charge carriers.

27. The apparatus of claim 14, wherein said electrode is an oxide-metal electrode.

28. A method of tunneling charge carriers by controlling a polarization-selective barrier profile in a tunnel junction, said method comprising:
a) providing a first spin filter;
b) providing a second spin filter adjacent said first spin filter; and
c) tunneling said charge carriers through said first spin filter and said second spin filter.

29. The method of claim 28, further comprising:
a) selecting for said first spin filter a material having a first magnetization M₁;
b) selecting for said second spin filter a material having a second magnetization M₂; and
c) altering a relation between said first magnetization M₁ and said second magnetization M₂, thereby changing said polarization-selective profile.

30. The method of claim 29, further comprising applying an external magnetic field to alter said second magnetization M₂.

31. The method of claim 29, further comprising applying an applied electric field across said tunnel junction to promote said tunneling of said charge carriers.

32. The method of claim 28, wherein said tunnel junction is operated in a predetermined temperature range.
